(19) United States
(12) Patent Application Publication
(10) Pub. No.: US 2026/0352166 A1
(43) Pub. Date: Nov. 5, 2026

(54) Amplifier for musical instruments

(71) Applicant: TONE SPRING, Avezzano (IT)

(72) Inventor: MARIA LUISA CESARIO, ROME (IT)

(21) Appl. No.: 19/110,441

(22) PCT Filed: Nov. 22, 2023
(86) PCT No.: PCT/IT2023/050262

§ 371 Date: Mar. 11, 2025

(30) Foreign Application Priority Data
Nov. 30, 2022 (IT) 102022000024429

(51) Int. Cl. H03F 3/183

(52) U.S. Cl. CPC H03F 3/183; H03F 2200/03

(57) ABSTRACT

This patent describes concept and ways of implementing an audio amplifier having the special feature of driving the loudspeaker without generating the electroacoustic noise. This is generated in analogic circuits, consequence of sound and heat propagation in the materials of circuit components under the presence of an audio signal. A structure more resilient to electromechanical stress is less prone to generating such noise, and adequate circuits are also able to cancel his residual effect. Compared to prior art, the invention greatly improves the sound quality, giving musicians more freedom of tonal research and greater ease of musical performance. A similar improvement is also made when the invention is used to drive speakers for music production studios, as well as for all applications where the best quality of sound is required.

### TECHNICAL FIELD

The embodiments of the present description refer to the concept of amplifier and preamplifier for audio frequencies and consist of apparatuses suitable for any type of musical instrument and voice, and for driving loudspeakers for music or concert production studios, as well as for any electronic application where higher sound quality is useful.

### BACKGROUND OF ART

Experts in the technical field of audio amplifiers are convinced that, to perceive sound as more pleasant, euphonic distortion would be added to the signal coming from a microphone or pickup of musical instrument. In fact, although Hi-Fi amplifiers are characterized by very low distortion figures measured instrumentally, the reproduced sound is judged to be too cold, as “incinerated” in the timbre and harmonics, to the point that the instrument, e.g. a violin, loses intonation. This would explain why musicians continue to prefer old tube amps to more reliable and hum-free transistor ones, and audiophiles express aversion to HiFi amplifiers, preferring hi-end type apparatuses characterized by euphonic distortion provided by valves.

The paradigm of the alleged euphonic distortion represents the main focus of the article by R. O. Ham: “Tubes Versus Transistors”, 43th Convention of the Audio Engineering Society, New York, Sept 14, 1972. According to this idea, mere effects of a psychological-subjective nature (then, not objective defects still present in electronics) would push listeners to judge the sound of solid-state devices as unpleasant and unnatural because their dramatically low rate of all distortion figures reflect also in insufficient dose of euphonic distortion. This means that old valve apparatuses provided better sound for merely fortuitous reasons, since transistors were not available yet.

According to the Ham's idea, patents for decades have been focusing on the emulation of valve characteristics by modern solid-state implementations, see for example: “Guitar Amplifier”, US Patent No. 20130136278A1 by Quilter (2013), “Vacuum Tube Amplification Unit”, US20150170627A1 by Hummel, (2015), “Method and apparatus for distortion of audio signals and emulation of vacuum tube amplifiers” by N. Gallo, US Pat. No. 20080218259A1 (2008), “Guitar Amplifier” US Patent No. 20130136278A1 by Quilter (2013), and “Vacuum Tube Amplification Unit”, US20150170627A1 by Hummel, (2015), “Semiconductor amplifier with tube amplifier characteristics”, U.S. Pat. No. 4,809,336A di Eric K. Pritchard (1987), “Solid state audio amplifier emulating a tube audio amplifier”, U.S. Pat. No. 5,467,400A by Bruce Keir, and also in “Solid state circuit for emulating tube compression effect”, U.S. Pat. No. 5,524,055A Jack C. Sondermeyer, in “Solid state emulation of vacuum tube audio power amplifiers”, U.S. Pat. No. 5,636,284A by E. K. Pritchard (1994), in “Adjustable distortion guitar amplifier”, U.S. Pat. No. 4,495,640A, by Douglas R. Frey (1982).

The same issue of exploiting the benefic effect of tube distortion is addressed in the so-called hi-end audio amplifiers which, unlike Hi-Fi amplifiers (having almost zero rate of measured distortion), are conceived according with the intent of emulating the measured harmonic distortion patterns recovered in amplifiers that reported best public success, see for example: “Amplifier and preamplifier circuit” by Karsten, 2001 U.S. Pat. No. 6,242,977B1, and “High fidelity floating bridge amplifier”, by Berry 2002, U.S. Pat. No. 6,747,513B1.

In summary, prior art generally conceives audio amplifiers in which certain alterations are added to input signal to improve sound quality. This type of benefic distortion lies in the electrical characteristics of valves that can be fully emulated by solid state apparatuses. Despite that, musicians continue to prefer amps based on early tube circuitry rather than complex solid-state implementations designed to emulate the electrical characteristics of tubes.

Such problem that persists for decades is now solved here by the invention described below. Tests carried out have demonstrated that at the basis of poor sound quality judgement of an audio amplifier is the presence of a defect of technical nature of circuits of prior art, then, not of a psychological/subjective type attributable to the listener, as experts believe. Consequently, valves and suitable electronics are less prone to originate a physical phenomenon which prior art ignores the existence, which hereafter is defined as: the electroacoustic or anti-harmonic noise or even the anti-harmonic noise. Electroacoustic noise is intrinsic to circuit components and is the effect of electromechanical stresses that occur on a microscopic scale in the materials making up circuit components, due to interaction between the enormous number of audio signal harmonic elements and the natural ways (phonons) by which sound and heat propagate in materials of circuit components. As main effect of such interaction, harmonic components of the audio signal are altered in amplitude and phase, more strongly as larger is the signal amplitude and the harmonic components' number. The latter aspect prevents this type of noise from being detected instrumentally, since measures trust so far on only too little tonal components, absolutely insufficient to account for the extraordinary harmonic richness of even a banal musical instrument chord.

The electroacoustic noise level can be assessed only by statistic tests of listening comparison, the human ear being very sensitive to detecting the harmonic richness of sounds.

It is thus not a matter of intentionally adding any presumed euphonic distortion to audio signal, but it is rather necessary to eliminate all types of distortion, even the new type one that escapes from measurements. It follows that the problem of sound quality of amplifiers is far from being solved by prior art but is definitively solved by the present invention.

As crucial aspect for music reproduction, electroacoustic noise alters the harmonics that give character of a sound, which thus undergoes a sort of homologation impressed in prior art circuits. This alteration is detrimental and not useful even if a distortion device is used, because musicians want however to control the effects for artistic and expressive reasons. This is impossible for the electroacoustic noise since it is intrinsic to all prior art apparatuses.

FIG. 1 concerns a well-known guitar amplifier that, as mentioned, is designed accordingly with tube amplifiers of over half a century ago. In the figure the signal from the instrument's pick-up is in the unbalanced configuration, from the input to the output stage, see modules U5a, U5b. The figure also shows the output stage which includes the push-pull devices that power the output transformer. The figure shows the circuit parts used for regulating gain and volume (master) respectively, as well as those of the tone controls of the different channels designed to produce different sound modes (clean or distorted).

As common feature of all the best amplifiers for musical instruments of prior art, the voltage amplifier stages are in the common cathode (“white” cathode) configuration, cascaded, as shown in FIG. 2. See also the stages U1a (general preamplifier) and U2a (voltage amplifier of CH1) indicated in FIG. 1.

Moreover, semiconductor switches are employed on the signal path with respect to the amplifier module comprising the device U2a, see FIG. 2. The electronic circuits generally use resistors and potentiometers of the metal film or carbon mixture, or plastic film type, which offer good characteristics of low electromagnetic noise picked up by the power supply section. Regarding the constructive characteristics of capacitors and active devices (valves), no specific indications are generally given by manufacturers.

Where they declare offering special creations, perhaps handmade, those manufacturers generally do not justify these choices that thus appear to be dictated by mere commercial or empirical reasons with the aim of satisfying something that relates only to suggestion, not to sound quality.

To drive speaker, prior art amplifiers for musical instruments employ different solutions: i) full band driving only (as in the case with electric guitars to resort the way of the first amplifiers derived from those of the cinemas of the early years of the last century) or, ii) two or more loudspeakers, each dedicated to different frequency ranges utilizing crossover networks that generally are embedded into the speaker. The latter is the case with bass and other instruments and voice, as well as with speakers for recording studios and concert halls.

### DISCLOSURE OF INVENTION

Differently from prior art, the idea is followed here according to which electronic circuit does not have to add any type of artifacts to audio signal: not only those that would have a purported euphonic effect, but also possible artifacts of a technical-objective nature of which prior art ignores the existence, because these artifacts escape instrumental measurements.

It is therefore matter of carrying out listening comparison tests among standard equipment and prototypes designed for performing the inventive steps, whose results are reported here. To perform tests, signals produced directly by musical instrument pick-up or microphone have been used as input, in place of recorded pieces albeit of high quality. Indeed, the latter are in any case affected electroacoustic noise intrinsic to recording electronics.

To suppress electroacoustic noise, it is necessary to use differential amplifier techniques that offer high common mode rejection, being that type of noise of the latter type. It is also necessary to connect directly the amplifier to the speaker, i.e., without interposition of passive crossover networks. The latter can originate, under large signal at the output of amplifier, stronger mechanical stress in the components'materials and, consequently, larger electroacoustic noise.

An exploitation of differential amplifier is considered by Rozemblit, in U.S. Pat. No. 5,604,461 (1997 ) “Transformerless output vacuum tube audio amplifier”, which discloses an audio power amplifier connected to a long-tailed pair circuit preamplifier and an output buffer/bias stage providing an output terminal to be connected to loudspeaker. Quilter, in U.S.2013/132678A1, shows a guitar amplifier including solid state module simulating overdrive distortions of vacuum tube amplification stages (via clipping and power sagging effects) equipped with buffering, equalization and gain control. Robling, in U.S. Pat. No. 9,306,510 B1, shows a dual solid state and vacuum tube amplifier combined with a two-way crossover designed to be directly to the loudspeakers. Malcolm, in “Pontoon Amplifier constructions incorporating error feedback location of floating power supplies”, AES, 60 East 42^{nd} Street, Room 2520, New York 10165-2520, USA, shows how to improve an audio amplifier design using floating bridge setup, end Berry, in U.S. Pat. No. 7,187,233 B1 (2007), shows a floating bridge amplifier comprising a long-tailed pair amplification stage. Further examples are in: “Differential-input amplifier circuit” U.S. Pat. No. 4,272,728A by H. A. Wittlinger, “Differential amplifier” by K. Ishiguro, Y. Takahashi, US patent 2010/001797A1, and “Amplifying an audio signal” by D. J. Mate, US 2008/008335A1.

Technical choices to solve the problem posed here are, however, different and counter-intuitive: all resistors, i.e. not only those on the signal line and also those located in the portions of the circuit where there is low circulating power, are of the wound-wire type, without however having any support which increases their heat dissipation. In fact, what counts for purpose of reducing the electroacoustic noise is a larger cross section of the resistive element of resistors. The elimination of accessory structures and materials used to increase heat dissipation is all to the advantage of smaller dimensions, lower weight and lower cost. Resistive elements of film type are instead more prone to generate electroacoustic noise.

Circular shape cross section provides greater intrinsic mechanical stiffness to the overall structure which is thus less prone to generating electroacoustic noise.

It is known that wire wound resistors are very sensitive to picking electromagnetic noise from mains.

This problem is solved here by using polarized wire wound resistors, i.e. in which the winding direction is shown. A certain resistance value is therefore achieved by means of one or more pairs of resistors connected in series and polarized in the opposite direction and kept side by side. As a result, the overall component obtained from the pair of resistors is almost non-inductive type, while being cheap to make. In it, the resistive element cross-section is even greater than in the case of using only one component with double the resistance value, to the advantage of less electroacoustic noise. In fact, more massive is the resistive element, lower is the capacity to generate noise, owing to greater stiffness against electromechanical stress. Thus, the greater the thickness of the resistive element, stronger the noise suppression effect is. Thickness greater than ten thousandths of a millimeter is acceptable: the optimal solution is thickness of 30 thousandths of a millimeter or more.

Furthermore, due to diffusive character of sound and heat propagation in the materials of electronic components, electroacoustic noise is led to pervade the entire circuit, thus reaching portions even not located along the signal path, as power supplies, constant current sources, etc. The use of capacitors with appropriate construction characteristics (see below) prevents the spread of the noise from being amplified at the amplifier output.

Counter-intuitive is also the need to operate with the output stage implemented in solid state not in A class, as it is generally expected in the HiFi audio field, see for example, Bongiorno, “Audio amplifier”, U.S. Pat No. 4,229,706A (1980). To have low electroacoustic noise, solid state output devices must operate in AB class even biased with relatively low current to not heat too much the output devices. In fact, by actively cooling them below ambient temperature (over five degrees) offers an added benefit to help solve the problem posed here. As said, indeed, electroacoustic noise depends on audio signal interaction with the electric field associated with the natural ways in which heat propagates in materials that make up electronic components, so that electric field has lower intensity when components are kept under lower temperatures. Furthermore, electric field is stronger when the active regions of a solid-state component are smaller: this is the case of integrated circuits whose use is thus excluded. Under same operating conditions, solid state devices of larger mass and dimensions (such as that required for operation at high voltages and large currents) are less prone to the onset of electroacoustic noise.

In addition, also capacitors would respect constructive characteristics useful to help reduce electroacoustic noise. Consequently, they are of the axial type. i.e., with cylindrical armatures (which are stiffer for reasons intrinsic to geometry). Suitable dielectrics are of robust characteristics such as polyester or polypropylene fiber.

Similarly, electron tubes suitable for high quality sound applications have the electrodes and related mechanical support and heat dissipation parts have the largest possible mass and are made with material layers of cylindric shape at least for the major portion. In the case of using solid state components, instead, these are not of the integrated circuit type, their active portion has mass as large as possible, such as is the case for components operating at high voltages and large currents.

Electroacoustic noise alters, as said, the harmonic components of an audio signal, not only by randomly suppressing a portion of these, but also by altering its phase. From this derives both the sense of incineration of the sound perceivable by only one single speaker, and poor reconstruction of the stereophonic image when suitable speakers are used. Negative feedback is detrimental in this regard because it alters the phase relations of harmonic components of the signal. Negative feedback produces effects which are part of the electroacoustic noise.

To extend the symmetrical circuit topology up to the output stage, the known Circlotron circuitry is exploited, see: “Parallel Opposed Power Amplifiers”, U.S. Pat. No. 2,705,265 by C. T. Hall, (1955), and “Audio amplifier”, U.S. Pat. No. 4,229,706A by Bongiorno (1980). It is a bridge configuration that uses floating power supplies and active power devices having the same electrical conduction mode, i.e. electrons only, which is congenial for low electroacoustic noise.

Circlotron concept is also used in patents by Karsten and Berry, with the difference that, in the invention described here, to diminish electroacoustic noise: i) components and circuit topology of the mentioned type are used, ii) negative feedback is avoided and, iii) the solid-state output stage, although like Bongiorno circuitry, has the important difference of operating in class AB, not in class A.

The problem posed here is different from the prior art one of Hi-Fi amplifiers, i.e. those with a harmonic distortion rate even much lower than the minimum ascertainable by listening (which is of the order of one percent). Instead, for the invention, harmonic distortion simply below hearing threshold is sufficient, while electroacoustic noise (to which the human ear is very sensitive because it has to do with the harmonic richness that the ear can well perceive as a characteristic of even simple sounds), more usefully, is dramatically reduced thanks to technical choices described here.

The exercise carried out to achieve the invention has shown that even solid-state components, resistors and capacitors kept under lower temperatures are the site of diminished electroacoustic noise. This requirement, for obvious reasons, does not apply to valves which, however, are less prone to generating electroacoustic noise due to greater extension and greater mass of the electrodes, especially if they have cylindric shape. More specifically, an amplifier triode for low-power applications (0.5 watt-1 watt), suitable for low electroacoustic noise, uses for the anode and elements for mechanical support and thermal dissipation, layers of about 0.10 mm-0.15 mm thick. As a result of the inventive step, using a thickness of 0.4 mm results in significant electroacoustic noise reduction. The same criterion of using electrodes with a thickness greater than at least a factor of two greater also applies to higher power tubes (50 watts). In these low electroacoustic noise devices, standard thickness of about 0.4 mm in common tubes is increased to at least 0.8 mm. The mentioned characteristics represent the true choice to conceive new tubes properly dedicated to high quality audio purposes.

To diminish the electroacoustic noise, electron tubes are polarized with relatively high anode current (close to central design value of the tube). This favors the establishment of a greater resilience of the electrode system to generate electromechanical stresses that, consequently, results in lower electroacoustic noise.

It follows that the use of electrodes of greater mass enable operating with a lower anode current (with consequent energy saving from the mains), which corresponds to a lower electroacoustic noise level compared to the case in which tube standard version is used, which would require operating, instead, with larger anode current to obtain same suppression noise effect.

Even a smaller local electric field in the presence of audio signal of given amplitude plays in favor of valves compared to solid state components, thanks to greater interelectrode gap. The consequent smaller electric field has in fact the benefic result of reducing the interaction between the audio signal electromagnetic field coupled with the background phonon field.

As important difference with respect to prior art embodiments, as said, the invention operates exclusively by directly connecting the power output stage with the loudspeaker, without the use of transformers or crossover networks.

Electroacoustic noise has proven to be an additive phenomenon, in the sense that each of the technical choices mentioned contributes to reducing it. In case some of these choices are omitted, the noise increases sensitively but, in any case, some audio quality improvement persists thanks to presence of the remaining suitable choices. This explains why a certain prior art amplifier can give slightly better sound quality than others since, for fortuitous reasons, one or more of these choices should be included.

Consequently, manufacturers mislead of having discovered a recipe for enhancing distortion of euphonic type, not for probably reducing an unknown type of noise detrimental for sound quality, as stated here.

The intrinsic inability of prior art electronics to return audio signal in the integrity of the harmonic components penalizes voice and all musical instruments as well. It is known, in fact, that violins are rarely amplified precisely due to the consequent penalization of intonation caused by electroacoustic noise intrinsic to prior art electronics. The same is true for double bass especially when uses the fiddlestick that generates sound much richer of harmonics, and, consequently, larger electroacoustic noise. This instrument sometimes needs amplification, for example, in jazz music. Double bass is, indeed, among musical instruments the one that in fuller way generates harmonic components, starting with those at a lowest frequency than other instruments. This instrument, in addition to guitar (which is also an instrument that has notoriously poor intonation, like violins), finds considerable advantage in timbre and sound character when used with the invention.

Thanks to lower electroacoustic noise, it is finally possible to restore the audio signal in the integrity of harmonic components, including their phase, which also allows a perfect reconstruction of the stereophonic image. Any audio device in which a new standard of greater sound quality is required can therefore be realized with the invention. Importantly, the true digital audio potential can finally be effectively exploited by creating, via the mentioned technical choices, analogic circuitries that interface with digital modules of devices like mixers, CD players, etc. In fact, digital to analogic and analogic to digital interfaces generally needs amplifier, buffer and filter modules which, if implemented according to contents of this description, offer low electro-acoustic noise to every audio digital device.

It is known that often music production studios use speakers equipped with very expensive audio transducers, even those made with special materials and actively or passively driven by the amplifier.

As discussed above, the weaker point for quality sound is rather represented by the amplifier, not the audio transducer. Consequently, by the invention it is possible to obtain good sound quality even using conventional and cheaper transducers. With similar reasoning, even a musical instrument of a not too precious type can, by using the invention, outclass those of the finest quality, but equipped with prior art electronics.

### BRIEF DESCRIPTION OF DRAWINGS

FIG. 1. Block diagram of a typical prior art valve guitar amplifier.

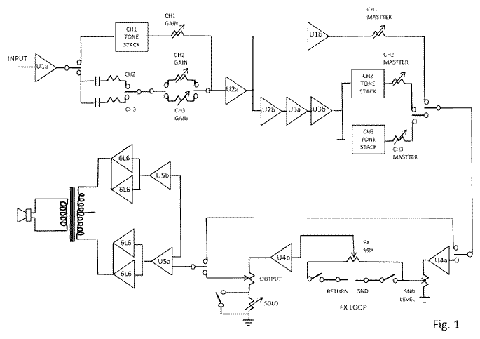

FIG. 2. Diagram of the input stage of a typical valve amplifier for guitar of prior art.

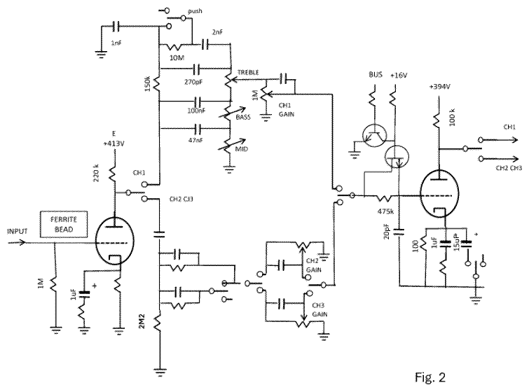

FIG. 3. Wiring diagram of a particular way of making an amplifier for musical instruments with low electroacoustic noise with the output stage equipped with a floating bridge module operating on full frequency band.

FIG. 4. Details of the circuitry comprised in the filter and separation stage 40 and in the filter and bias stage 400 indicated in FIG. 3.

FIG. 5. Details of the output stage of the amplifier of FIG. 3 equipped with two floating bridge modules operating on two different frequency bands.

### BEST MODE OF CARRYING OUT THE INVENTION

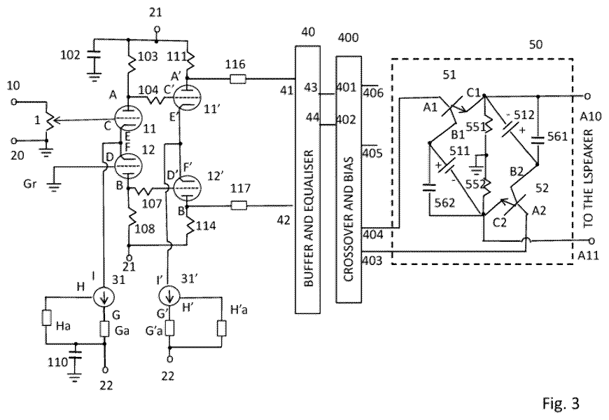

Due to the need to exclusively use symmetrical circuit topology (differential amplifiers), unbalanced signal (e.g. coming from the guitar pick-up) is rendered in balanced form by means of the long-tailed pair differential amplifier circuit which includes devices 11, 12 and the relative source of constant current 31, see FIG. 3. The required voltage amplification is obtained by cascading one or more differential amplifier stages connected in cascade, as exemplified by the one that includes devices 11′, 12′ and the related constant current source 31′.

Since differential amplification stages mainly require resistors as passive components, these are required having a stiff structure as the resistive element, that is, they are of the wire-wound type in which this resistive element has the largest possible cross-section.

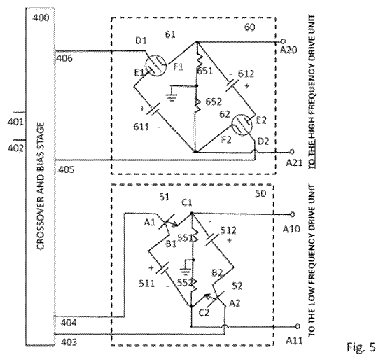

Due to need to avoid negative feedback, a drop occurs at high frequencies in voltage amplifier stages, especially with solid-state implementation, so the frequency response is compensated by inserting suitable modules 40 and 400 indicated in FIG. 3. The former has the function of separation and filter; the latter has the function of further filter and polarization of the output devices. In order not to increase the electroacoustic noise, the least possible number of circuit elements is employed. Filter circuits are required to flatten the frequency response, but to help solve the problem, multiway active amplifier approach is convenient (see more ahead), since the goal is easier achieved in relatively narrow band amplifier modules. In this regard, module 400 performs a cross-over function for actively driving loudspeakers, see FIG. 5. In the latter case, filter network is of the known “Unity Gain Single-Feedback” type, in which the required constant current source (for buffer circuits) is made using an active type of device rather than simple resistor. In summary, for buffer modules and for cross-over filter modules, only circuits including common cathode, common emitter and common source circuits are used, respectively, for valves, junction transistors and mosfets implementation.

Except for valves, keeping electronic components to reach below the ambient temperature, the best result of lower electroacoustic noise is obtained considering the output amplifier stage option shown in FIG. 5. The low frequency output stage is implemented with transistors to avoid the use of many power tubes connected in parallel, which leads to too high demand from mains and larger cost and bulk as well. Power tubes should be used for of the output stages operating at frequencies only above 200 Hz-300 Hz; however, but the choice of using transistor in Circlotron configuration even for the remaining frequency ways is useful for reducing costs and bulk, while allowing active cooling of the whole electronics.

The following topics help to better understand the characteristics of the present invention by highlighting the substantial differences with the content of previous patents, whose technical problem is in any case very different, i.e., producing lower instrumentally measured distortion figures, while the present invention suppresses a type of noise detectable only by statistic tests of listening comparison.

For low frequencies, a transistor implementation of the respective output stage is used in the invention, like what was done in U.S. Pat. No. 9,306,510B1 (2016) by Robling “Frequency dependent dual solid-state and vacuum tube power amplifier-section instrument amplifier”. The latter is suitable for bass guitars that often use two-way driving speakers, while the invention here described is valid also for other musical instruments and voice as well. The invention has indeed demonstrated that tonal characteristics desired by musicians do not necessarily require full band loudspeakers, as in the case of early guitar systems that manufacturers emulate for top end products. However, Robling patent addresses a technical problem different from that of the present description, since that patent is silent on the constructive characteristics of circuit components, or on proper circuit operating conditions useful for diminishing electroacoustic noise.

Rozemblit in U.S. Pat. No. 5,604,461A (1997), “Transformerless output vacuum tube audio amplifier”, shows an audio amplifier that is without inter-stage coupling with capacitors, while a similar type of coupling is indeed compatible with solution of the problem posed in present invention, if capacitors are of suitable type. Furthermore, Rozemblit patent shows a “long tailed pair” circuit using a simple resistor as a constant current source, while in the present description such source includes an active device. The latter possibility is instead provided, for example, in the Takehara U.S. Pat. No. 4,241,313 (1980), “Audio power amplifier”, but none of them provide any indications on the constructive characteristics of circuit components.

In King's patent WO 87/07554 (1987) “Sound reproduction system”, the amplifier is connected to the speakers by means of a passive cross-over filter network, which includes resistors, capacitors and even inductors. Resistors are of wire type for the required passive crossover application.

However, in those patents, no construction characteristics are recommended for such resistors, except that they comply with a quality standard for special applications. A similar request is made for the type of capacitors to be used in filter network. Conversely, in the present description, as mentioned, loudspeaker is mandatorily connected directly to the amplifier in an active way, i.e., by filter stages equipped in the amplifier and built using the same criteria discussed for suppressing electroacoustic noise. As a further special feature of the invention, parameters (mass and geometry) relating to the constructive characteristics of passive and active components to be used in the circuit are specified.

A version of low electroacoustic noise amplifier suitable for musical instruments is schematized in FIG. 3, in an implementation able to drive any type of speaker. In this embodiment the voltage amplifier stage is implemented with valves and drives a solid-state power output stage. Lower electroacoustic noise is obtained by actively cooling the circuit components of at least ten degrees centigrade. By implementing the whole circuit in solid state, excellent reduction of the electroacoustic noise is obtained.

If the input signal is of the unbalanced type, it is fed into the gain potentiometer (1) of the amplifier. To reduce electroacoustic noise more markedly, potentiometers are made by means of switches with, e.g., 12 steps, with one or two banks depending on whether the single or balanced signal is to be handled. Resistors of the polarized wire-wound type, as described above, are mounted on switches to function as potentiometer.

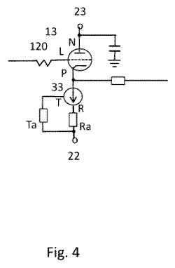

Differential voltage amplifier configuration (tubes 11,12 and current source comprising device 31) forms balanced signal. FIG. 3 shows cascade connection of a further voltage amplification stage (tubes 11′,12′ and current source which includes the device 31′) to obtain the desired gain while further reducing electroacoustic noise thanks to DC coupling interstage. Such four-tube stage is then a.c. coupled to the next buffer stage (40), whose circuits are of the type indicated in FIG. 4, i.e. comprising device (13) equipped with the respective constant current source, made with constant current source device (33) of the active type.

To diminish electroacoustic noise, the same type of buffer circuit of FIG. 4 is used to conceive buffer and filter/equalizing functions of stage 40, and even polarization functions of stage 400, see FIG. 3, which provides crossover function in the case of two or more ways amplifier embodiment, see FIG. 5.

Importantly, as said, four ways of frequencies in active drive is the best solution for the following reasons: i) easier achievement of flat response in band, considering the lack of negative feedback, ii) useful frequency balancing/equalization is automatically offered.

To obtain the necessary response accuracy of the cross-over filter which serves for the active driving of the loudspeakers indicated in FIG. 5, filter modules use the technical note “Unity Gain Single-Feedback Realization” (see: “Introduction to modern network theory”, McGraw-Hill Education 2014), because it only uses buffer stages (rather than operational circuits with appropriate voltage gain). These buffer stages use discrete active devices, as indicated in FIG. 4. By this choice, amplifier stages are avoided which, having to be of the differential type, would imply a more complicated circuit with a greater number of components, thus leading to an increase in electroacoustic noise.

Buffer stage 40 of the amplifier chain can eventually drive a wave squaring device or other types of distortion tools, such as a spring unit for reverb mode. Consequently, distorted sound too presents low electroacoustic noise and consequent better sound performance, in the sense that even the artificially added harmonic components remain unchanged like those of the input signal. Thus, by the invention, for the first time, natural and artificially altered sounds are perceived in their fullness and harmonic integrity. This applies if the same type of circuit and components criteria described above are used for the distortion module. I.e., circuitry necessary for amplifying, buffering and distorting the signal use, mandatorily: i) balanced signal circuits of the same type, ii) differential type amplification stages, iii) buffer circuits appropriate for balanced signals, iv) no negative feedback and, mainly, suitable types of passive and active components.

The module, or modules, of the output power stage for high frequencies, see FIG. 5, use the original Circlotron tube configuration. The module for low frequencies is transistor implemented, but it is different from that of Bongiorno because: i) it is polarized in AB class (as said) and, ii) provides for a standard voltage multiplication network, i.e., not the one used by Bongiorno.

Solid state output stage (51) uses bipolar junction transistors because, compared to mosfets, have the advantage of: i) exhibiting lower crossover distortion under load required operation of Circlotron operating in AB class, ii) having lower cost and, iii) withstanding larger collector currents. On the other hand, to drive the output transistors mosfets are used, with the advantage of offering lower load to voltage amplifier stage, even when it is implemented with tubes, as in FIG. 3.

Power tubes are biased with a suitable choice of a resistive divider included in the filter and bias module (400), to obtain sufficiently large bias current (indicatively of the order of a few hundred milliamps for power triode for audio frequencies). This relatively large current is necessary to give the electrode system larger resilience to stresses occurring on a microscopic scale. For the same reason, tubes used in the driver, filter and separation stages are polarized with current slightly lower than the maximum routine value foreseen for these tubes.

Output power transistors 51,52 are biased via resistive divider included in module 400. Thermal stabilization of the output power transistors is obtained by at least one diode kept in thermal contact of the power transistor casing, and via voltage multiplier function circuit. High DC voltage source (of about 80 V) is chosen to power output transistors, while the bias current is relatively low (approximately, about 30 mA), as necessary for less device's heating and, consequently, lowering the electroacoustic noise.

As a general consideration, in addition to electrolytic filter of power supplies, at least one capacitor with the characteristics indicated above is also connected from the voltage supply lines and ground, close the amplifier circuit. This contributes to reducing the electroacoustic noise. Finally, base/gate resistors transistors (with a value of the order of 100 ohms) with stabilization function are indispensable.

What is claimed is:

1. A low electroacoustic noise amplifier for musical instruments implemented with electron tubes or solid state comprising the following portions: a) an input stage comprising at least first and second input terminal means (10,20) suitable for receiving at least an input signal, b) a preamplifier stage comprising at least a portion with long tailed pair circuitry and a ground terminal (Gr), c) a buffer and filter stage (40) comprising at least first and second input terminals (41,42) and at least first and second output terminals (43,44), d) a filter and bias stage (400) comprising at least first and second input terminals (401,402) and at least first, second, third and fourth output terminals (404,403,406,405), e) an output stage comprising at least a floating bridge module (50) operating on at least a first frequency range and comprising at least first and second DC power sources (511,512), f) at least first and second output terminal means (A10,A20) to connect one or more loudspeakers operating in said first frequency range,
said electronic tube comprising at least a first portion called anode, at least a second portion used as mechanical support of the anode, at least a third portion used for thermal dissipation of the anode,
said portion with long tailed pair circuitry of said preamplifier stage comprising: i) first and second preamplifier devices (11,12) each comprising first and second input terminals (A, B), first and second terminals (C, D) and first and second output terminals (E, F), ii) a constant current source comprising a constant current source device (31) comprising a power supply terminal (G), a control terminal (H), and an output terminal (I),
said first and second input terminals (A, B) of said first and second preamplifier devices (11,12) being respectively connected by means of connection to a same first DC voltage source (21) referred to said ground terminal (Gr),
said control terminal (C) of said first preamplifier device (11) being connected by means of connection to said input terminal means (10),
said first and second output terminals (E, F) of said first and second preamplifier devices (11,12) being connected both to each other and to said output terminal (I) of said constant current source device (31) of said constant current source of said first portion of said preamplifier stage,
said power supply terminal (G) of said constant current source device (31) being connected by connection means (Ga) to a second DC voltage source (22) referred to ground terminal (Gr),
said control terminal (H) of said constant current source device (31) of said constant current source being connected by connection means (Ha) to said second DC voltage source (22),
said buffer and filter stage (40) comprising at least a buffer device (13) and at least a constant current source comprising a constant current source device (33),
said buffer device (13) comprising an input terminal (L), a power supply terminal (N), and an output terminal (P),
said constant current source device (33) comprising a power supply terminal (R), a control terminal (T), and an output terminal,
said power supply terminal (N) of said buffer device (13) being connected to a third source of DC voltage (23) referred to ground terminal (Gr),
said output terminal (P) of said buffer device (13) being connected by means of connection to the output terminal of said constant current source device (33) of said constant current source of said buffer and filter stage (40),
said power supply terminal (R) of said constant current source device (33) being connected by means of connection (Ra) to said second DC voltage source (22),
said control terminal (T) of said first constant current source device (33) being connected by means of connection (Ta) to said second DC voltage source (22),
said first and second output terminals (43,44) of said buffer and filter stage (40) being respectively connected to said first and second input terminals (401,402) of said filter and bias stage (400),
said first floating bridge output module (50) comprising at least first and second output devices (51,52) each comprising respectively first and second input terminals (A1,A2), first and second (B1,B2) power supply terminals, first and second output terminals (C1,C2), first and second (511,512) DC power sources,
said first and second input terminals (A1,A2) of said first and second output devices (51,52) of said output module (50) being respectively connected by connection means to said first and second output terminals (404,403) of said filter and bias stage (400),
said first DC power source (511) being connected between said power supply terminal (B1) of said first output device (51) of said first output module (50) and said output terminal (C2) of said second output device (52) of said first output module (50),
said second DC power source (512) being connected between said power supply terminal (B2) of said second output device (52) of said first output module (50) and said output terminal (C1) of said first output device output (51) of said first output module (50),
said first and second output terminal means (A10,A20) to be connected to a load respectively between said first and second output terminals (C1,C2) of said first and second output devices (51,52) of said first output module (50),
at least one of said portions of the amplifier comprising at least a potentiometer or a capacitor or a resistor,
said resistor being of the wire-wound type having a circular section at least for the most part which is greater than or equal to 15 thousandths of a millimeter.

2. An amplifier as in claim 1 in which said resistor exhibits the winding direction.

3. An amplifier as in claim 1 in which said potentiometer is made using resistors of the wire-wound type in which the wire has cross-section equal or greater than 0.015 millimeter.

4. An amplifier as in claim 1 in which said capacitor has axial geometry and is of the polyester or polypropylene type with working voltage greater than 500 volts.

5. An amplifier as in claim 1 in which said output stage comprises at least a second floating bridge output module (60) operating on at least a second frequency range beyond said first frequency range,
said second floating bridge output module (60) comprising third (611) and fourth (612) DC power source and third and fourth output terminal means of the amplifier (A20, A21) for the connection of one or more loudspeakers driven on said second frequency range,
said second floating bridge output module (60) comprising first and second output devices (61,62) each comprising respectively first and second input terminals (D1,D2), first and second power supply terminals (E1,E2), first and second output terminals (F1,F2),
said input terminals (D1,D2) of said first and second output devices (61,62) of said second floating bridge output module (60) being respectively connected by connection means to said third and fourth output terminals (406,405) of said filter and bias stage (400),
said third DC power source (611) being connected between said power supply terminal (E1) of said first output device (61) of said second floating bridge output module (60) and said output terminal (F2) of said second output device (62) of said second floating bridge output module (60),
said fourth DC power source (612) being connected between said power supply terminal (E2) of said second output device (62) of said second floating bridge output module (60) and said output terminal (F1) of said first device output (61) of said second floating bridge output module (60),
said output terminals (F1,F2) of said first and second output devices (61,62) of said second floating bridge output module (60) being respectively connected by means of connection to said third and fourth output terminal means of amplifier (A20,A21).

6. An amplifier as in claim 1 in which at least one of said first, second and third portions of said electron tube is of curved shape for at least one third of the total surface of said portion.

7. An amplifier as in claim 1 in which the thickness of materials of at least one of said first, second, and third portions of said electron tube is more than 0.1 millimeter.

8. An amplifier circuit as in claim 1 in which at least one of said electron tubes is biased with current equal to at least two thirds of the maximum of the central design value of said tube.

9. An amplifier as in claim 1 in which at least one of said output devices of said output modules of said output stage is implemented in solid state and is biased with current not exceeding five tens of milliamps.

10. An amplifier as in claim 1 which includes a heat pump device comprising a module equipped with a first portion which absorbs heat and a second portion which emits heat in the room, with first and second power supply terminals connected to a source of electrical power,
the casing of at least one of said devices and components other than an electron tube comprised in at least one of said portions of the amplifier being kept at least five degrees centigrade below the room temperature by direct or indirect contact of such casing with said first portion of said heat pump device absorbing heat.
